(19) United States
(12) Patent Application Publication
(10) Pub. No.: US 2015/0145034 A1
(43) Pub. Date: May 28, 2015

(54) LDMOS STRUCTURE AND MANUFACTURING METHOD THEREOF

(71) Applicant: UNITED MICROELECTRONICS CORPORATION, Hsinchu (TW)

(72) Inventors: Chiu-Te Lee, Hsinchu County (TW); Kuan-Yu Chen, New Taipei City (TW); Ming-Shun Hsu, Miaoli County (TW); Chih-Chung Wang, Hsinchu City (TW); Ke-Feng Lin, Taipei City (TW); Shu-Wen Lin, Hsinchu County (TW); Shih-Teng Huang, Taichung City (TW); Kun-Huang Yu, New Taipei City (TW)

(73) Assignee: UNITED MICROELECTRONICS CORPORATION, Hsinchu (TW)

(21) Appl. No.: 14/088,432

(22) Filed: Nov. 24, 2013

(51) Int. Cl. H01L 29/78; H01L 29/10; H01L 21/02; H01L 21/265; H01L 29/66; H01L 29/08

(52) U.S. Cl. CPC H01L 29/7816; H01L 29/7835; H01L 29/66659; H01L 29/66689; H01L 29/0878; H01L 21/02164; H01L 21/0217; H01L 21/265; H01L 29/1095
USPC 257/336; 438/286

(57) ABSTRACT

A LDMOS structure including a semiconductor substrate, a drain region, a lightly doped drain (LDD) region, a source region and a gate structure is provided. The substrate has a trench. The drain region is formed in the semiconductor substrate under the trench. A LDD region is formed in the semiconductor substrate at a sidewall of the trench. The source region is formed in the semiconductor substrate. The gate structure is formed on a surface of the semiconductor substrate above the LDD region between the drain region and the source region. A method for manufacturing the LDMOS structure is also provided.

### FIELD OF THE INVENTION

The present invention relates to a MOS structure and manufacturing method thereof, and more particularly to a LDMOS structure and manufacturing method thereof.

### BACKGROUND OF THE INVENTION

In general, for a lateral diffused metal-oxide-semiconductor (hereinafter “LDMOS”) device, it is very important to improve device performance and low power consumption. Therefore, the LDMOS device's turn on resistance (hereinafter “Ron”) and break down voltage (hereinafter “BVdss”) are key factors contributing to device performance and power consumption.

A conventional LDMOS device uses a drift region to release the surface electric field, so it should enlarge the device size and that will suffer the device's Ron. Hence, it is desirable to find new approaches for solving the problem.

### SUMMARY OF THE INVENTION

In accordance with an aspect, the present invention provides a LDMOS structure including a semiconductor substrate, a drain region, a lightly doped drain (LDD) region, a source region and a gate structure. The substrate has a trench. The drain region is disposed in the semiconductor substrate under the trench. A LDD region is disposed in the semiconductor substrate at a sidewall of the trench. The source region is disposed in the semiconductor substrate. The gate structure is disposed on a surface of the semiconductor substrate above the LDD region between the drain region and the source region.

In an embodiment, a spacer is disposed on sidewalls of the trench and the gate structure.

In an embodiment, the spacer is completed by a three-layer structure composed of a silicon oxide layer, a silicon nitride layer, and a silicon oxide layer.

In an embodiment, a drift region is formed in the semiconductor substrate under the gate structure.

In an embodiment, the drift region is formed in a deep N-well under the gate structure between the LDD region and a low voltage P-well.

In an embodiment, a P-body region is formed in the low voltage P-well.

In an embodiment, the drain region is formed in a low voltage N-well disposed in the deep N-well under the gate structure.

In accordance with another aspect, the present invention provides a method for manufacturing a LDMOS structure. Firstly, a semiconductor substrate is provided. Then, a gate structure on a surface of the semiconductor substrate is formed. Next, a trench in the semiconductor substrate at one side of the gate structure is formed. Then, a first doping process is performed to form a LDD region in the semiconductor substrate at a sidewall of the trench. Finally, a second doping process is performed to form a drain region and a source region in the semiconductor substrate at two sides of the gate structure. Besides, the drain region is formed in the semiconductor substrate under the trench.

In an embodiment, forming a spacer on the sidewalls of the trench and the gate structure before the second doping process is performed.

In an embodiment, forming the spacer comprises forming a silicon oxide layer, a silicon nitride layer, and a silicon oxide layer sequentially.

In an embodiment, forming a drift region in the semiconductor substrate under the gate structure.

In an embodiment, the drift region is formed in a deep N-well under the gate structure between the LDD region and a low voltage P-well.

In an embodiment, forming a P-body region in the low voltage P-well.

In an embodiment, an annealing process is performed after the trench is formed and before the first doping process is performed.

### BRIEF DESCRIPTION OF THE DRAWINGS

The above objects and advantages of the present invention will become more readily apparent to those ordinarily skilled in the art after reviewing the following detailed description and accompanying drawings, in which:

FIGS. 1A-1D are cross-sectional views, combined to illustrate a method for manufacturing a LDMOS structure in accordance with an embodiment of the present invention and the resulting LDMOS structure thereof; and

FIG. 2 schematically illustrates a LDMOS structure completed by a method in accordance with an embodiment of the present invention in a top view.

### DETAILED DESCRIPTION OF PREFERRED EMBODIMENTS

The present invention will now be described more specifically with reference to the following embodiments. It is to be noted that the following descriptions of preferred embodiments of this invention are presented herein for purpose of illustration and description only. It is not intended to be exhaustive or to be limited to the precise form disclosed.

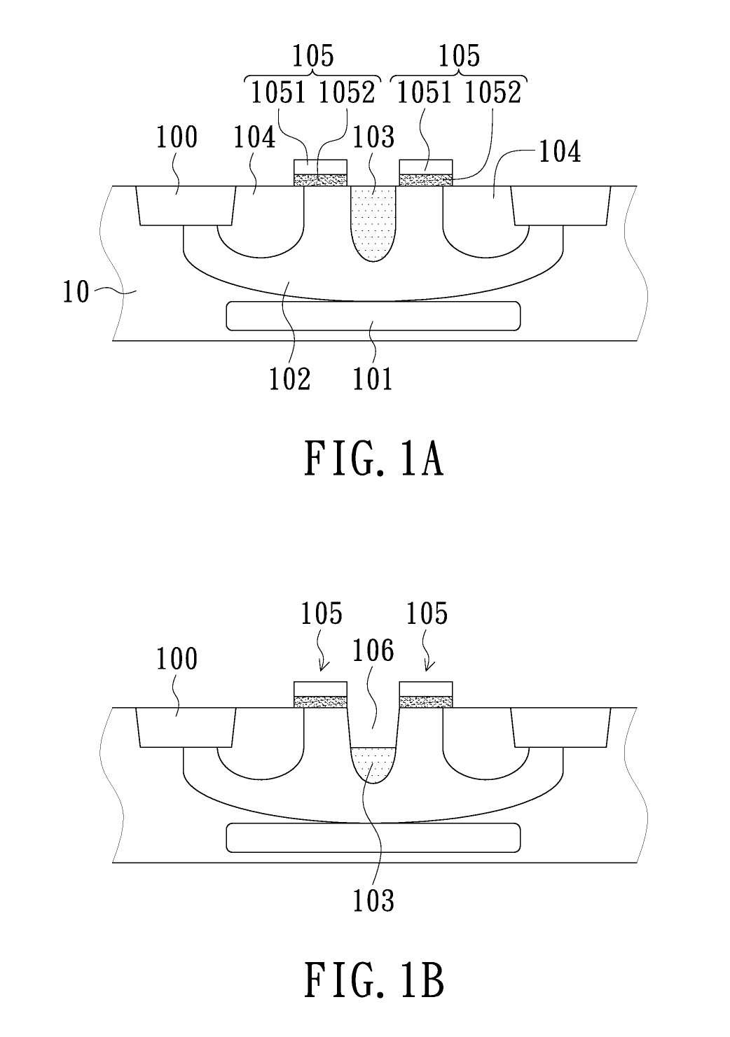

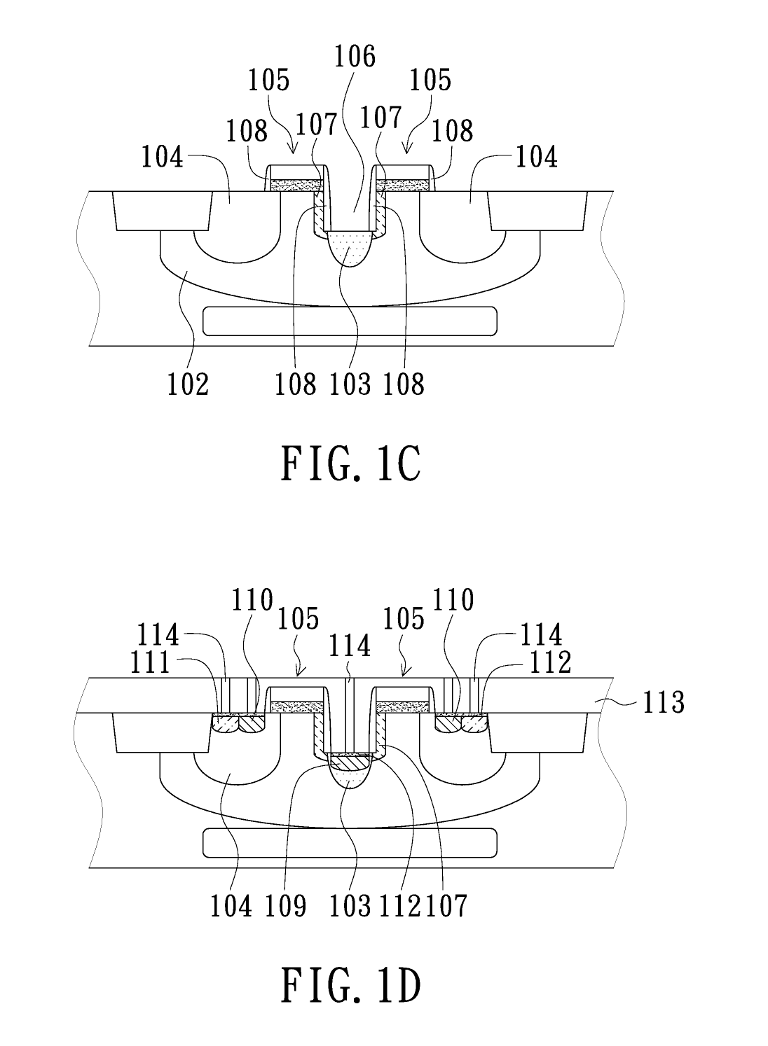

With reference to FIG. 1A˜FIG. 1D, a method for manufacturing a LDMOS structure in accordance with an embodiment of the present invention and the resulting LDMOS structure thereof are schematically illustrated. As shown in FIG. 1A, the P-type semiconductor substrate 10 has a shallow trench isolation (STI) 100 and some doped regions, such as, a N+ buried layer 101, a deep N-well 102, a low voltage N-well (LVNW) 103 and a low voltage P-well (LVPW) 104 thereon; and further also has a gate structure 105 thereon, so as to achieve an etched semi-finished product. Each gate structure 105 is mainly composed of a gate conducting layer 1051 and a gate dielectric layer 1052. In addition, a depth of the LVNW 103 is shallower than a depth of the LVPW 104.

Referring to FIG. 1B, an area for a drain at one side of the gate structure 105 exposed from a mask (not shown) is etched to form a trench 106. In one embodiment of the present invention, an etching process for forming the STI 100 and a depth thereof may be applied to the etching process for forming the trench 106. Additionally, an annealing process may be performed after the trench 106 is formed so as to repair some of damages on surfaces of the trench 106 caused by the etching process. Thus, the annealing process is beneficial for following steps and the device performance.

Please see FIG. 1C. A first doping process is performed to form a lightly doped drain (LDD) region 107 under each gate structure 105. Then, a spacer 108 is formed on sidewalls of the trench 106 and the gate structure 105, wherein the spacer 108 may be a three-layer structure composed of a silicon oxide layer, a silicon nitride layer, and a silicon oxide layer (not shown). Therefore, a drift region is formed in the deep N-well 102 under the gate structure 105 between the LDD region 107 and the LVPW 104.

With reference to FIG. 1D, a second doping process is performed to form an N-type drain region 109 and an N-type source region 110 respectively in the LVNW 103 and the LVPW 104 at two sides of the gate structure 105. Furthermore, a third doping process may be performed to form a P-body region 111 in the LVPW 104, wherein the N-type source region 110 is disposed between the P-body region 111 and the drift region in the deep N-well 102. Next, a self-aligned silicidation (SALICIDE) process is performed to form a metal silicide layer 112 on the N-type drain region 109, the N-type source region 110 and the P-body region 111, respectively. Then, a dielectric layer 113 is formed on the surface of the substrate 10, and penetrated by contact holes on the N-type drain region 109, the N-type source region 110 and the P-body region 111. Finally, a plurality of contact electrodes 114 are formed in the contact holes.

Furthermore, a doping concentration of the N-type drain region 109 is greater than that of the LDD region 107. The doping concentration of the LDD region 107 is greater than that of the deep N-well 102.

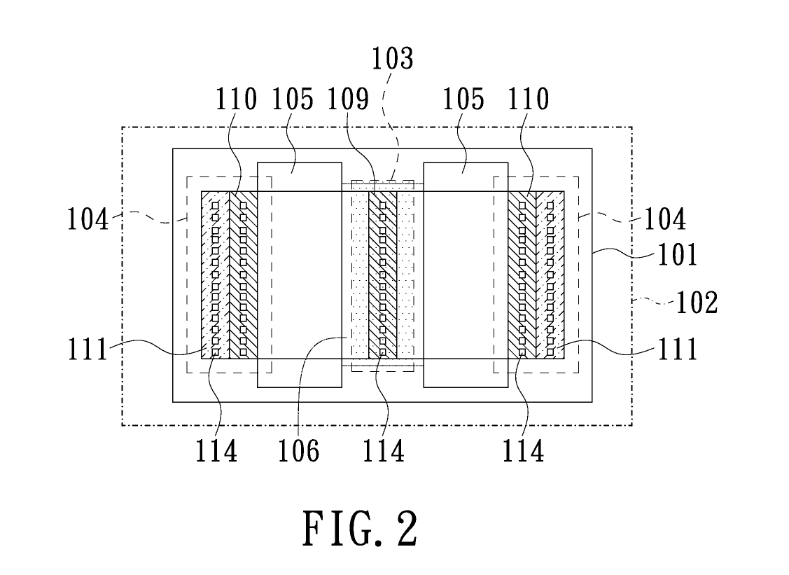

With reference to FIG. 2, a LDMOS structure in accordance with one embodiment of the present invention is schematically illustrated in a top view. The LDMOS structure may be completed by the above method in accordance with the embodiment of the present invention. The configuration of the N+ buried layer 101, the deep N-well 102, the LVNW 103, the LVPW 104 and the gate structure 105 in the P-type semiconductor substrate 10 is explicitly shown in FIG. 2. The trench 106 is disposed between the two gate structures 105. The N-type drain region 109 is disposed in the trench 106. The N-type source region 110 and the P-body region 111 are disposed beside the gate structures 105, respectively. The contact electrodes 114 are formed on the N-type drain region 109, N-type source region 110 and the P-body region 111.

In summary, the present invention is to change the conventional geometric structure of the drain region of the LDMOS structure to create a recessed drain structure. Thus, without increasing the horizontal dimension, the desired channel length may be acquired in the drift region along the vertical direction of the LDMOS structure. Consequently, the pitch size of the LDMOS structure may be shrunk and lower Ron and higher BVdss may be maintained.

While the invention has been described in terms of what is presently considered to be the most practical and preferred embodiments, it is to be understood that the invention needs not be limited to the disclosed embodiment. On the contrary, it is intended to cover various modifications and similar arrangements included within the spirit and scope of the appended claims which are to be accorded with the broadest interpretation so as to encompass all such modifications and similar structures.

What is claimed is:

1. A lateral diffused metal-oxide-semiconductor (LDMOS) structure, comprising:
a semiconductor substrate having a trench;
a drain region formed in the semiconductor substrate under the trench;
a lightly doped drain (LDD) region formed in the semiconductor substrate at a sidewall of the trench;
a source region formed in the semiconductor substrate; and
a gate structure formed on a surface of the semiconductor substrate above the LDD region between the drain region and the source region.

2. The LDMOS structure according to claim 1, further comprising a spacer disposed on sidewalls of the trench and the gate structure.

3. The LDMOS structure according to claim 2, wherein the spacer has a three-layer structure composed of a silicon oxide layer, a silicon nitride layer, and a silicon oxide layer.

4. The LDMOS structure according to claim 1, further comprising a drift region formed in the semiconductor substrate under the gate structure.

5. The LDMOS structure according to claim 4, wherein the drift region is formed in a deep N-well under the gate structure between the LDD region and a low voltage P-well.

6. The LDMOS structure according to claim 5, further comprising a P-body region formed in the low voltage P-well.

7. The LDMOS structure according to claim 5, wherein the drain region is formed in a low voltage N-well disposed in the deep N-well under the gate structure.

8. A method for manufacturing a LDMOS structure, comprising providing a semiconductor substrate;
forming a gate structure on a surface of the semiconductor substrate;
forming a trench in the semiconductor substrate at one side of the gate structure;
performing a first doping process to form a lightly doped drain (LDD) region in the semiconductor substrate at a sidewall of the trench; and
performing a second doping process to form a drain region and a source region in the semiconductor substrate at two sides of the gate structure, respectively, wherein the drain region is formed in the semiconductor substrate under the trench.

9. The method according to claim 8, further comprising forming a spacer on the sidewalls of the trench and the gate structure before the second doping process is performed.

10. The method according to claim 9, wherein forming the spacer comprises forming a silicon oxide layer, a silicon nitride layer, and a silicon oxide layer sequentially.

11. The method according to claim 8, further comprising forming a drift region in the semiconductor substrate under the gate structure.

12. The method according to claim 11, wherein the drift region is formed in a deep N-well under the gate structure between the LDD region and a low voltage P-well.

13. The method according to claim 12, further comprising performing a third doping process to form a P-body region in the low voltage P-well.

14. The method according to claim 8, further comprising performing an annealing process after the trench is formed and before the first doping process is performed.
